(19) United States
(12) Patent Application Publication
(10) Pub. No.: US 2026/0180579 A1
(43) Pub. Date: Jun. 25, 2026

(54) LEVEL SHIFTER

(71) Applicant: Renesas Design (UK) Limited, Bourne End (GB)

(72) Inventor: Martin Färber, München (DE)

(73) Assignee: Renesas Design (UK) Limited, Bourne End (GB)

(21) Appl. No.: 18/989,875

(22) Filed: Dec. 20, 2024

(51) Int. Cl. H03K 19/0185; H03K 19/003

(52) U.S. Cl. CPC H03K 19/018521; H03K 19/00315

(57) ABSTRACT

A level shifter for shifting a voltage signal from a first voltage domain to a second voltage domain including an input circuit configured to receive the voltage signal in the first voltage domain, an output circuit configured to output the voltage signal in the second voltage domain, and a protection circuit configured to prevent reverse current flow between the input circuit and the output circuit.

The present disclosure relates to a level shifter for shifting a voltage signal from a first voltage domain to a second voltage domain.

### BACKGROUND

A voltage domain refers to the voltage range within which a device functions and is dependent on the supply voltages provided to the device. For example, if a device receives a first supply voltage of 5V and a second supply voltage of 0V, the device is operable within a range of 0V to 5V and can provide an output signal within this range. A supply voltage of 0V may be referred to as the ground voltage. The supply voltages may be provided via power rails.

In certain applications, it is necessary to shift a voltage from one voltage domain to another. For example, if a control signal for a power switch is in a different voltage domain from the control signal generator, it may be necessary to shift the control signal to the appropriate voltage domain for controlling the power switch. A level shifter is a device for shifting a signal from one voltage domain to another.

For a static voltage domain, the first supply voltage may be variable, whilst the second supply voltage, being the ground, is fixed. In a flying voltage domain, both first and second supply voltages may be variable, but with a constant difference between the first and second supply voltages.

FIG. 1A is a schematic of a known apparatus 100 comprising two sequential level shifters 102, 104 coupled in series. The apparatus 100 further comprises a power gate driver 108 and a power device 110.

The level shifter 102 transfers the input signal 112 to the most negative (or positive) output voltage, the level shifter transfers the input signal 112 to the flying output domain, with a ground potential never being higher than the output ground of the level shifter 104. In the same manner the signal 112 might be upshifted first and then (down-) shifted to the output voltage domain. In some cases, optical or magnetic signal transfer might be used as part of the level shifting procedure.

FIG. 1B is a schematic of a known level shifter 114 for shifting a signal from an initial voltage domain to a lower voltage domain (WO2008/101548 A1). The level shifter 114 receives an input signal 60 and provides output signals 65, 66. The level shifter 114 comprises inverters 48, 49, 52, 53; transistors 42, 45, 43, 46, 44, 47; nodes 61, 63, 62, 64; resistors 50, 51; and diodes 54, 55.

### SUMMARY

It is desirable to provide an improved level shifter.

According to a first aspect of the disclosure there is provided a level shifter for shifting a voltage signal from a first voltage domain to a second voltage domain comprising an input circuit configured to receive the voltage signal in the first voltage domain, an output circuit configured to output the voltage signal in the second voltage domain, and a protection circuit configured to prevent reverse current flow between the input circuit and the output circuit.

Optionally, the first voltage domain is a flying voltage domain and/or the second voltage domain is a flying voltage domain.

Optionally, the input circuit is configured to operate in the first voltage domain and the output circuit is configured to operate in the second voltage domain.

Optionally, the first voltage domain is the voltage range from a first supply voltage to a second supply voltage, and the second voltage domain is the voltage range from a third supply voltage to a fourth supply voltage.

Optionally, the protection circuit comprises one or more rectifier elements, each of the rectifier elements being configured to prevent reverse current flow between the input circuit and the output circuit.

Optionally, one or more of the rectifier elements comprises a diode or a bipolar transistor.

Optionally, the diode is a p/n diode, a Zener diode or a Schottky diode.

Optionally, the input circuit comprises a pull up circuit coupled to the output circuit via a first portion of the protection circuit, the first portion of the protection circuit being configured to prevent reverse current flow from the output circuit to the pull up circuit, thereby preventing reverse current flow between the input circuit and the output circuit, and/or a pull down circuit coupled to the output circuit via a second portion of the protection circuit, the second portion of the protection circuit being configured to prevent reverse current flow from the pull down circuit to the output circuit, thereby preventing reverse current flow between the input circuit and the output circuit.

Optionally, the output circuit comprises a latch circuit configured to provide the voltage signal in the second voltage domain, wherein the pull up circuit is coupled to the latch circuit via the first portion of the protection circuit, the first portion of the protection circuit being configured to prevent reverse current flow from the latch circuit to the pull up circuit, thereby preventing reverse current flow between the input circuit and the output circuit, and/or the pull down circuit is coupled to the latch circuit via the second portion of the protection circuit, the second portion of the protection circuit being configured to prevent reverse current flow from the pull down circuit to the latch circuit, thereby preventing reverse current flow between the input circuit and the output circuit.

Optionally, the first voltage domain is the voltage range from a first supply voltage to a second supply voltage, the second voltage domain is the voltage range from a third supply voltage to a fourth supply voltage, the second voltage domain is positive when the fourth supply voltage is greater than the third supply voltage, and/or the second supply voltage is greater than the first supply voltage, and/or the third supply voltage is greater than the first supply voltage, the second voltage domain is negative when the second supply voltage is greater than the fourth supply voltage, and/or the first supply voltage is greater than the third supply voltage, and the pull up circuit is configured to control a state of the latch circuit based on the voltage signal in the first domain, as received, when the second voltage domain is negative, and the pull down circuit is configured to control the state of the latch circuit based on the voltage signal in the first domain, as received, when the second voltage domain is positive.

Optionally, the pull up circuit is configured to control the state of the latch circuit by providing a first pull up signal to a first input terminal of the latch circuit and/or by providing a second pull up signal to a second input terminal of the latch circuit, and the pull down circuit is configured to control the state of the latch circuit by providing a first pull down signal to the first input terminal of the latch circuit and/or by providing a second pull down signal to the second input terminal of the latch circuit.

Optionally, the first pull up signal is a first pull up current pulse, the second pull up signal is a second pull up current pulse, the first pull down signal is a first pull down current pulse, and the second pull down signal is a second pull down current pulse.

Optionally, the first pull up current pulse is a set pulse for the latch circuit and the second pull up current pulse is a reset pulse for the latch circuit, or the first pull up current pulse is a reset pulse for the latch circuit and the second pull up current pulse is a set pulse for the latch circuit, or the first pull down current pulse is a set pulse for the latch circuit and the second pull down current pulse is a reset pulse for the latch circuit, or the first pull down current pulse is a reset pulse for the latch circuit and the second pull down current pulse is a set pulse for the latch circuit.

Optionally, the latch circuit comprises a cross coupled inverter pair.

Optionally, the output circuit comprises a common mode rejection circuit coupled to the latch circuit, and the latch circuit is configured to provide the voltage signal in the second voltage domain via the common mode rejection circuit.

Optionally, the level shifter comprises a first cascode circuit coupled between the first portion of the protection circuit and the latch circuit, and a second cascode circuit coupled between the second portion of the protection circuit and the latch circuit.

Optionally, the protection circuit comprises a first rectifier element, a second rectifier element, a third rectifier element and a fourth rectifier element, each of the first, second, third and fourth rectifier elements are configured to prevent reverse current flow between the input circuit and the output circuit, the first rectifier element is coupled to the first input terminal of the latch circuit and the third rectifier element, the second rectifier element is coupled to the second input terminal of the latch circuit and the fourth rectifier element, the pull up circuit is configured to provide the first pull up signal to the first input terminal via the first rectifier element, the pull up circuit is configured to provide the second pull up signal to the second input terminal via the second rectifier element, the pull down circuit is configured to provide the first pull down signal to the first input terminal via the third rectifier element, and the pull down circuit is configured to provide the second pull down signal to the second input terminal via the fourth rectifier element.

Optionally, the pull up circuit comprises a first pull up switch coupled to the first rectifier element and a second pull up switch coupled to the second rectifier element, and the pull down circuit comprises a first pull down switch coupled to the third rectifier element and a second pull down switch coupled to the fourth rectifier element.

Optionally, the pull up circuit comprises a first inverting AND gate configured to receive the voltage signal in the first domain and a first indicator signal, the first indicator signal being in a high state when the second domain is negative and in a low state when the second domain is positive, output a first inverting AND gate output signal, provide the first inverting AND gate output signal to control the switching operation of the second pull up switch, and a first inverter configured to receive the first inverting AND gate output signal, provide the inverted first inverting AND gate output signal to control the switching operation of the first pull up switch, and the pull down circuit comprises a second inverting AND gate configured to receive the voltage signal in the first domain and a second indicator signal, the second indicator signal being in a high state when the second domain is positive and in a low state when the second domain is negative, output a second inverting AND gate output signal, and provide the second inverting AND gate output signal to control the switching operation of the second pull down switch, and a second inverter configured to receive the second inverting AND gate output signal, provide the inverted second inverting AND gate output signal to control the switching operation of the first pull down switch.

Optionally, the input circuit comprises a pull up circuit and the output circuit comprises a pull down circuit, or the input circuit comprises the pull down circuit and the output circuit comprises the pull up circuit, and the pull up circuit is coupled to the pull down circuit via the protection circuit, the protection circuit being configured to prevent reverse current flow from the pull down circuit to the pull up circuit, thereby preventing reverse current flow between the input circuit and the output circuit.

According to a second aspect of the disclosure there is provided a power converter system comprising a level shifter for shifting a voltage signal from a first voltage domain to a second voltage domain comprising an input circuit configured to receive the voltage signal in the first voltage domain, an output circuit configured to output the voltage signal in the second voltage domain, and a protection circuit configured to prevent reverse current flow between the input circuit and the output circuit, and a power switch configured to operate in the second voltage domain, wherein the level shifter is configured to convert the voltage signal from the first voltage domain to the second voltage domain prior to the voltage signal being provided to the power switch.

It will be appreciated that the power converter system of the second aspect may include features set out in relation to the first aspect, and may include other features as described herein.

According a third aspect of the present disclosure there is provided a method of shifting a voltage signal from a first voltage domain to a second voltage domain using a level shifter, the method comprising receiving the voltage signal in the first voltage domain using an input circuit, outputting the voltage signal in the second voltage domain using an output circuit, and preventing reverse current flow between the input circuit and the output circuit using a protection circuit.

It will be appreciated that the method of the third aspect may include using and/or providing features set out in relation to the first and/or second aspects and may include other features as described herein.

### BRIEF DESCRIPTION OF THE DRAWINGS

The disclosure is described in further detail below by way of example and with reference to the accompanying drawings in which:

FIG. 1A is a schematic of a known apparatus comprising two sequential level shifters coupled in series, FIG. 1B is a schematic of a known level shifter from shifting a signal from an initial voltage domain to a lower voltage domain;

FIG. 2 is a further schematic of the level shifter of FIG. 1B;

FIG. 3 is a schematic of a level shifter in accordance with a first embodiment of the present disclosure;

FIG. 4 is a schematic of a specific embodiment of the level shifter in accordance with a second embodiment of the present disclosure;

FIG. 5 is a schematic of a specific embodiment of the level shifter in accordance with a third embodiment of the present disclosure;

FIG. 6 is a schematic of a specific embodiment of the level shifter in accordance with a fourth embodiment of the present disclosure;

FIG. 7 is a schematic of a power converter system comprising the level shifter and a power switch in accordance with a fifth embodiment of the present disclosure; and

FIG. 8 is a graph showing the relationship between the first voltage domain and examples of the second voltage domain.

### DETAILED DESCRIPTION

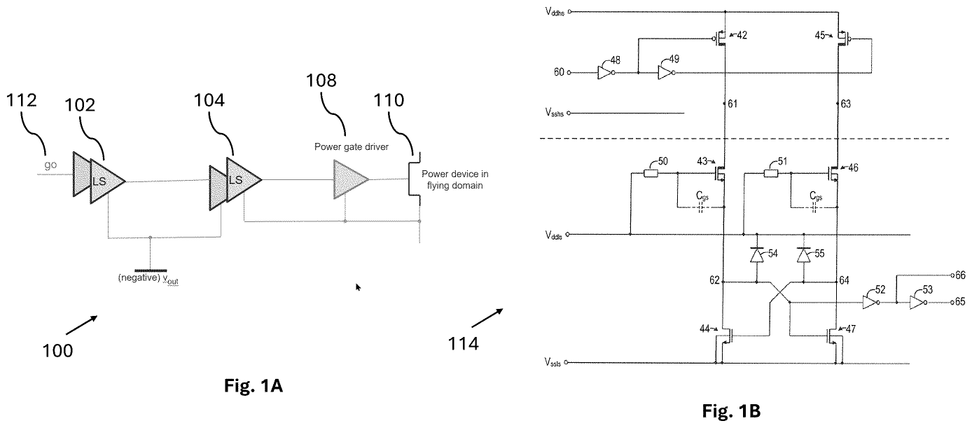

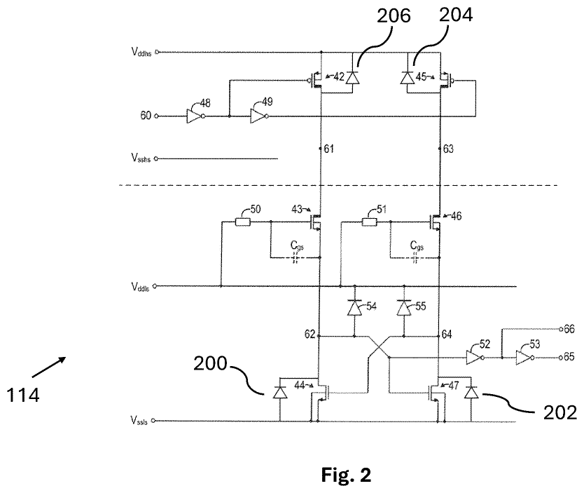

FIG. 2 is a further schematic of the level shifter 114 of FIG. 1B. In such conventional level shifters, the output rails Vddls, Vssls (i.e. the low side rails) are either at the same or at a lower potential than the input rails Vddhs, Vsshs (i.e. the high side rails).

In the present example, during normal operation, current would flow from the upper portion of the schematic to the lower portion. For example, current would flow from the node 61 to the node 62, and from the node 63 to the node 64.

If the level-shifter output domain (Vddls, Vssls rails) was to go to a higher potential than the input domain, then parasitic diodes 200, 202, 204, 206 of the transistors 42, 44, 45 and 47 could turn on.

The parasitic diodes 200, 202, 204, 206 can result in a “reverse current flow” within the level shifter 114. For example, from the node 62 to the node 61, and from the node 64 to the node 63.

This can have a variety of negative effects due to the different flow of current that may result in abnormal behaviour or even failure of the level shifter 114. It is desirable to provide a method to protect level shifters, such as the level shifter 114, from changes in the output domain that may cause reverse current flow.

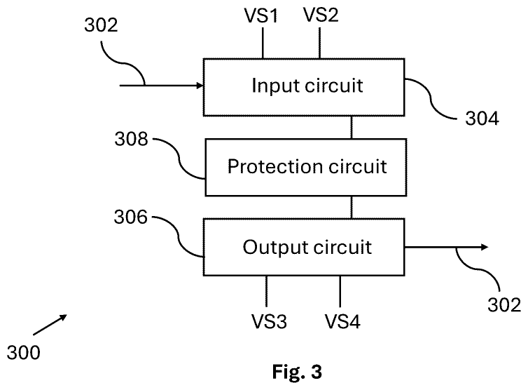

FIG. 3 is a schematic of a level shifter 300 for shifting a voltage signal 302 from a first voltage domain to a second voltage domain in accordance with a first embodiment of the present disclosure. The level shifter 300 comprises an input circuit 304 configured to receive the voltage signal 302 in the first voltage domain, an output circuit 306 configured to output the voltage signal 302 in the second voltage domain and a protection circuit 308 configured to prevent reverse current flow between the input circuit 304 and the output circuit 306.

The first voltage domain may, for example, be a static voltage domain or a flying voltage domain. The second voltage domain may, for example, be a static voltage domain or a flying voltage domain. For example, the first voltage domain may be a static voltage domain and the second voltage domain may be a flying voltage domain, such that, during operation the level shifter 300 shifts the voltage signal 302 from a static voltage domain to a flying voltage domain.

In a further embodiment, the input domain (being the first voltage domain) might be flying and the output domain (being the second voltage domain) may be static. In a further embodiment, both domains may be non-static (for example both flying domains).

If on-state information is transmitted back from a power switch to a digital controller via the level shifter 300 there would likely be level shifting from a flying to a static domain, as the controller normally sits in the static domain.

The first voltage domain may be a voltage range from a supply voltage VS1 to a supply voltage VS2. The second voltage domain may be a voltage range from a supply voltage VS3 to a supply voltage VS4.

The input circuit 304 may be configured to operate in the first voltage domain, for example by receiving the supply voltage VS1, VS2. The output circuit 306 may be configured to operate in the second voltage domain, for example by receiving the supply voltage VS3, VS4.

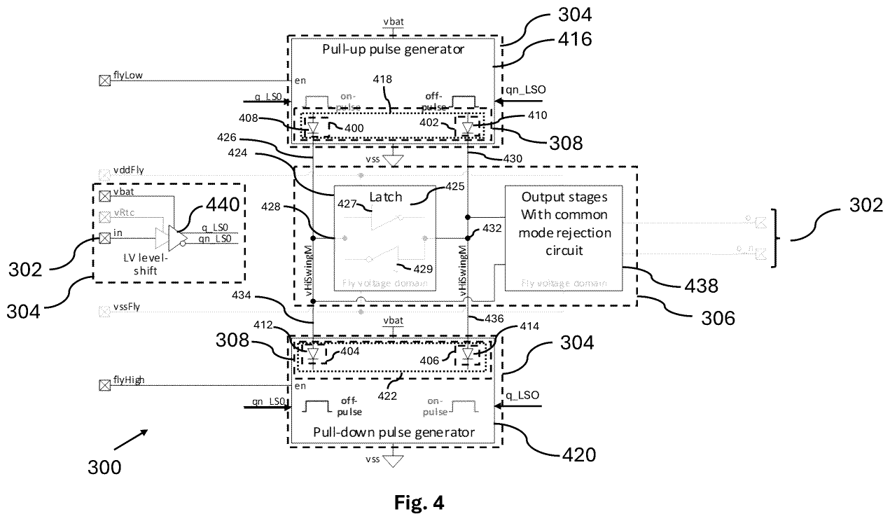

FIG. 4 is a schematic of a specific embodiment of the level shifter 300 in accordance with a second embodiment of the present disclosure.

The protection circuit 308 may comprise one or more rectifier elements, with each of the rectifier elements being configured to prevent reverse current flow between the input circuit and the output circuit. One or more of the rectifier elements may comprise a diode or a bipolar transistor. The diode may, for example, be a p/n diode, a Zener diode or a Schottky diode.

One or more of the rectifier elements may be implemented using a multi-junction rectifier element such as a thyristor. Normally there is one junction needed to conduct or isolate, and the other paths are (parasitic) paths which are part of (isolated) diodes in MOS or BCD technologies. In a further embodiment, one or more of the rectifier elements may be implemented using the beta of a bipolar and its reverse-blocking voltage.

In the present example, the protection circuit 308 comprises four rectifier elements 400, 402, 404, 406, and each of the rectifier elements 400, 402, 404, 406 comprises a diode 408, 410, 412, 414.

The input circuit 304 may comprise a pull up circuit 416 that is coupled to the output circuit 306 via a first portion 418 of the protection circuit 308. The first portion 418 of the protection circuit 308 may be configured to prevent reverse current flow from the output circuit 306 to the pull up circuit 416. In the present embodiment, the first portion 418 of the protection circuit 308 comprises the diodes 408, 410 which function to prevent the reverse current flow.

Alternatively, or additionally, the input circuit 304 may comprise a pull down circuit 420 that is coupled to the output circuit 306 via a second portion 422 of the protection circuit 308. The second portion 422 of the protection circuit 308 may be configured to prevent reverse current flow from the pull down circuit 420 to the output circuit 306. In the present embodiment, the second portion 422 of the protection circuit 308 comprises the diodes 412, 414 which function to prevent the reverse current flow.

The output circuit 306 may comprise a latch circuit 424 that is configured to provide the voltage signal 302 in the second voltage domain. The latch circuit 424 may comprise a cross coupled inverter pair 425 comprising inverters 427, 429. The latch circuit 424 may function as a set-reset (SR) latch as will be well known to the skilled person. Cross-coupled inverter pairs will be known by the skilled person and a similar latch structure is shown in U.S. Pat. No. 11,695,342B2.

In the present example, the rectifier elements 400, 402, 404, 406 are illustrated as part of the pull up and pull down circuits 416, 420. However, it will be appreciated that the rectifier elements 400, 402, 404, 406 may alternatively be separate from the pull up and pull down circuits 416, 420. For example, the rectifier elements 400, 402, 404, 406 may be part of the latch circuit 424 or may be separate from the pull up and pull down circuits 416, 420 and the latch circuit 424.

The pull up circuit 416 may be coupled to the latch circuit 424 via the first portion 418 of the protection circuit 308, such that reverse current is prevented from flowing from the latch circuit 424. The pull down circuit 420 may be coupled to the latch circuit 414 via the second portion 422 of the protection circuit 308, such that reverse current is prevent from flowing to the latch circuit 424.

In the present embodiment, the first voltage domain is the voltage range from a supply voltage vbat to a supply voltage vss, and the second voltage domain is the voltage range from a supply voltage vddFly to a supply voltage vssFly. In the present example the second voltage domain is a flying domain.

The second voltage domain may be negative if the second supply voltage is larger than the fourth supply voltage and/or first supply voltage is larger than the third supply voltage. The second voltage domain may be positive if the fourth supply voltage is larger than the third supply voltage and/or the second supply voltage is larger than the first supply voltage and/or the third supply voltage is larger than the first supply voltage.

During operation of the level shifter 300, the pull up circuit 416 may control a state of the latch circuit 424 based on the voltage signal 302 in the first domain, when the second voltage domain is negative.

The pull up circuit 416 may be configured to control the state of the latch circuit 424 by providing a pull up signal 426 to an input terminal 428 of the latch circuit 424 and/or by providing a pull up signal 430 to an input terminal 432 of the latch circuit 424. Each of the pull up signals 426, 430 may be current pulses. For example, one of the pull up signals 426, 430 may be a set pulse for the latch circuit 424 and the other of the pull up signals 426, 430 may be a reset pulse for the latch circuit 424.

During operation of the level shifter 300, the pull down circuit 420 may control the state of the latch circuit 424 based on the voltage signal 302 in the first domain, when the second voltage domain is positive.

The pull down circuit 420 may be configured to control the state of the latch circuit 424 by providing a pull down signal 434 to the input terminal 428 of the latch circuit 424 and/or by providing a pull down signal 436 to the input terminal 432 of the latch circuit 424. Each of the pull down signals 434, 436 may be current pulses. For example, one of the pull down signals 434, 436 may be a set pulse for the latch circuit 424 and the other of the pull down signals 434, 436 may be a reset pulse for the latch circuit 424.

It will be appreciated that the pull down signal 434 is the same signal as the pull up signal 426, and the pull down signal 436 is the same signal as the pull up signal 430 described previously. In FIG. 4, the signals at the anodes of the diodes 400, 402 are the pull-up signals, the ones at the cathodes of the diodes 404, 406 are the pull-down signals. The signals may be referred to as “high-swing signals” as they might go negative or positive relative to the output domain (as long as not protected by cascodes).

For example, vHiSwingM might go to about vssFly −0.7V when vssFly is high (e.g. 5V) and vss is low (e.g. 0V). Then the off-pulse current through diode 412 is drawn from the parasitic drain-bulk diode of the n-MOS in inverter 429. When the latch flipped, this n-MOS is turned on and a part of the current through diode 412 comes from the n-MOS channel.

Each of the two signals may also be referred to by the reference numerals 428, 432, (which refer to the latch input terminals 428, 432) if they are referred to as latch input signals.

In the present embodiment, the pull up circuit 416 functions as a pull-up pulse generator and the pull down circuit 420 functions as a pull-down pulse generator. Pull-up and pull-down pulse generators will be known to the skilled person and may be used to trigger the state change on the latch 424. In the present example, the level of the output domain (being the second domain) during the pulse is known. If the output domain is negative the signal “flyLow” is asserted and the pull up circuit 416 acts, if the output domain is positive the signal “flyHigh” is asserted and leads to a pulse from the pull down circuit 420.

When it is not known whether the second voltage domain is positive, negative, or if it experiences a transient during the set and reset procedure, on pulses may be generated simultaneously.

On-pulses may be generated on each of the pull-up and the pull-down pulse generator if the input has a rising edge, to set the latch. Off-pulses may be generated with both pulse generators to reset the latch.

In a specific embodiment, during the off-and on-pulses the input should not change and thus these pulses will not be interrupted from the input side. Only if the output changes from positive to negative or vice versa do the diodes can interrupt the on and off (current-)pulses.

In further embodiments, a constant pull-up signal or constant pull-down signal may be used (for example, there may constantly be current flowing towards the latch circuit 424, instead of pulses).

In the present embodiment, the output circuit 306 comprises a common mode rejection circuit 438 coupled to the latch circuit 424, with the voltage signal 302 in the second domain being provided from the latch circuit 424 via the common mode rejection circuit 438. Common mode rejection output stages, such as the common mode rejection circuit 438 will be known by the skilled person and may be used to cancel current pulses that may be generated by capacitive coupling when the flying domain jumps up or down.

In the present example, the input circuit 304 further comprises a LV level shifter 440 for separating the voltage signal 302 in the first domain into differential signals q_LSO, qn_LSO where qn_LSO is the inverse of q_LSO. The voltage signal 302 in the first domain is provided to the pull up circuit 416 and the pull down circuit 420 as the differential signals q_LSO, qn_LSO. Furthermore, the voltage signal 302 in the second domain is output by the output circuit 306 as differential signals o, o_n, where o_n is the inverse of o.

In a specific embodiment the cascodes may be separated from the rectifier elements. In a specific embodiment a multi p-n junction element like a thyristor or an npn transistor with variable base voltage may be used as a cascode.

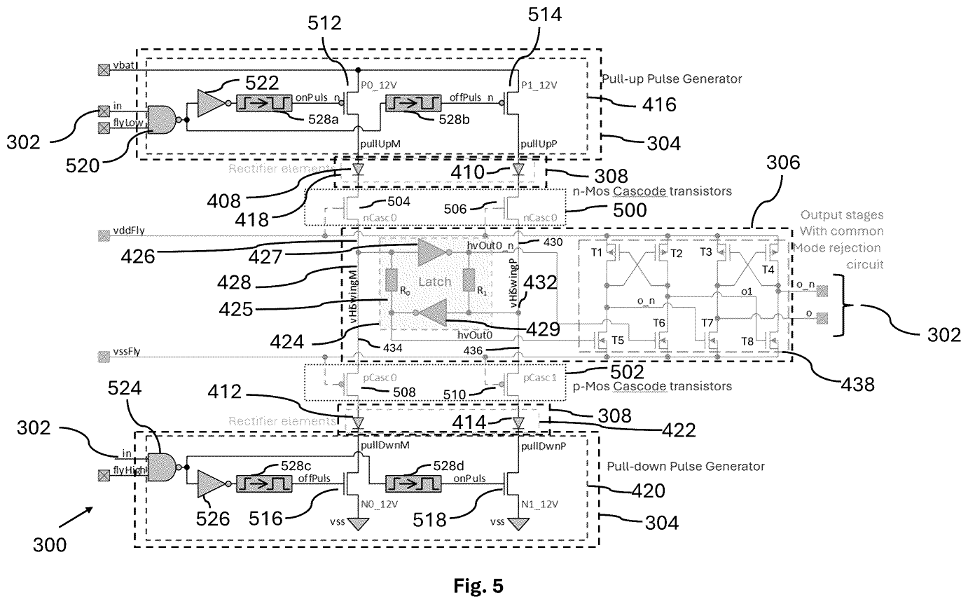

FIG. 5 is a schematic of a specific embodiment of the level shifter 300 in accordance with a third embodiment of the present disclosure.

In the present embodiment, the cross coupled inverter pair 425 comprises resistors R0, R1.

In the present embodiment, the level shifter 300 comprises cascode circuits 500, 502. The cascode circuit 500 comprises cascode transistors 504, 506 and the cascode circuit 502 comprises cascode transistors 508, 510.

Cascode transistors will be well known to the skilled person. Cascode transistors may protect the latch circuit 424 and the output stages from overvoltages. Further embodiments using cascode transistors may use additional circuitry to operate at low supply voltages. The function of the cascode transistors is separate to the rectifier elements.

In the present embodiment, the common mode rejection circuit 438 comprises transistors T1, T2, T3, T4, T5, T6, T7, T8.

In the present embodiment, the protection circuit 308 comprises the diodes 408, 410, 412, 414. It will be appreciated that in further embodiments, one or more of the diodes may be implemented using a different rectifier element, in accordance with the understanding of the skilled person.

As discussed previously, the rectifier elements provide reverse current protection and protect critical junctions in case the flying voltage output goes in the wrong direction (as without the rectifier elements the parasitic diodes in the cascode transistors and in the transistors of the Pulse generators would turn on). The reverse current protection function does not rely on the bi-directional characteristic of the level shifter 300 and therefore, it may be used in any kind of level shifter with a pull down or pull up path which is vulnerable to reverse current.

In the present embodiment, the diode 408 is coupled to the input terminal 428 of the latch circuit 424 and the diode 412; and the diode 410 is coupled to the input terminal 432 of the latch circuit 424 and the diode 414.

The pull up circuit 416 is configured to provide the pull up signal 426 to the input terminal 428 via the diode 408; the pull up circuit 416 is configured to provide the pull up signal 430 to the input terminal 432 via the diode 410; the pull down circuit 420 is configured to provide the pull down signal 434 to the input terminal 428 via the diode 412; and the pull down circuit 420 is configured to provide the pull down signal 436 to the input terminal 432 via the diode 414.

As discussed previously, it will be appreciated that the pull down signal 434 is the same signal as the pull up signal 426, and the pull down signal 436 is the same signal as the pull up signal 430. In FIG. 5, the signals at the anodes of the diodes 400, 402 are the pull-up signals, the ones at the cathodes of the diodes 404, 406 are the pull-down signals. The signals may be referred to as “high-swing signals” as they might go negative or positive relative to the output domain (as long as not protected by cascodes).

In the present embodiment, the pull up circuit 416 comprises a pull up switch 512 coupled to the diode 408 and a pull up switch 514 coupled to the diode 410. In the present embodiment, the pull down circuit 420 comprises a pull down switch 516 coupled to the diode 412 and a pull down switch 518 coupled to the diode 414.

One or more of the pull up switches 512, 514 and the pull down switches 516, 518 may comprise transistors such as MOSFETs.

The pull up circuit 416 may further comprise an inverting AND gate 520 configured to receive the voltage signal 302 in the first domain and an indicator signal flyLow. The indicator signal flyLow may indicate when the second domain is negative. For example, the indicator signal flyLow may be in a high state when the second domain is negative and in a low state when the second domain is positive.

The inverting AND gate 520 may be further configured to output an inverting AND gate output signal offPuls_n that is used to control the switching operation of the pull up switch 514.

It will be appreciated that the on-and off-pulses do not directly come from the NANDs 520, 524 or the inverters 522 and 526. The pulses coming out of these logic gates may be as long as the pulses at the input “in”. (The voltage signal 302 in the first voltage domain may have frequencies in the range of a few MHz in a specific embodiment and between 2 edges of the voltage signal 302 in the first voltage domain there may be far more than 10 ns. In a specific embodiment, the pulses in may have durations below 10 ns (to guarantee that the on-/off-pulses are never interrupted by input changes). Pulse generator circuits 528a, 528b, 528c, 528d (which may be Mono-Flops) generate the pulses on the edges at their inputs. As visible in the symbol for the pulse generator circuits 528a-528d on the schematic a pulse may only generated at the rising edge of the input of the pulse-generator 528a-528d.

The pull up circuit 416 may further comprise an inverter 522 configured to receive the inverting AND gate output signal offPuls_n and to provide an inverted version of the signal, being the inverted inverting AND gate output signal onPuls_n to control the switching operation of the pull up switch 512.

The pull down circuit 420 may further comprise an inverting AND gate 524 configured to receive the voltage signal 302 in the first domain and an indicator signal flyHigh. The indicator signal flyHigh may indicate when the second domain is positive. For example, the indicator signal flyHigh may be in a high state when the second domain is positive and in a low state when the second domain is negative.

The inverting AND gate 524 may be further configured to output an inverting AND gate output signal onPuls that is used to control the switching operation of the pull down switch 518.

The pull down circuit 420 may further comprise an inverter 526 configured to receive the inverting AND gate output signal onPuls and to provide an inverted version of the signal, being the inverted inverting AND gate output signal offPuls to control the switching operation of the pull down switch 516.

The present embodiment uses set and reset pulses at the input domain that flip the cross-coupled inverter pair 425 with current pulses. In the present embodiment, the rectifying elements (provided by the diodes 408, 410, 412, 414) couple the cascode transistors 504, 506, 508, 510 of the latch circuit 424 to the Pull-up and Pull-down pulse generators 416, 420.

Preferably, the rectifying elements mean that the parasitic junctions do not impact the functionality of the level shifter 300. Further embodiments may comprise circuitry to protect critical junctions against parasitic bipolars being turned on. For example, specific embodiments may limit the currents if parasitic bipolars are turned on with series resistances.

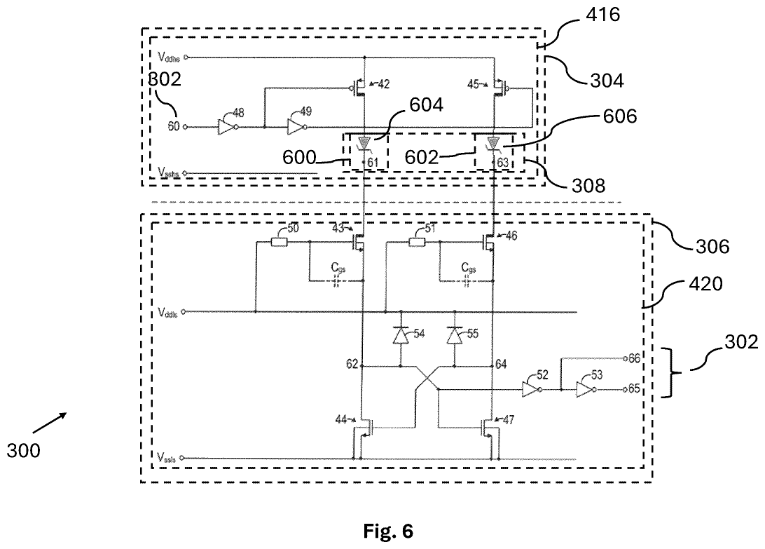

FIG. 6 is a schematic of a specific embodiment of the level shifter 300 in accordance with a fourth embodiment of the present disclosure.

The present embodiment shares features with the level shifter 114 of FIG. 1B with the addition of the protection circuit 308 comprising rectifier elements 600, 602, in which the rectifier element 600 comprises a diode 604 and the rectifier element 602 comprises a diode 606.

In the present embodiment, the input circuit 304 comprises the pull up circuit 416 and the output circuit 306 comprises the pull down circuit 420. The pull up circuit 416 is coupled to the pull down circuit 420 via the protection circuit 308. The protection circuit 308 is configured to prevent reverse current flow from the pull down circuit 420 to the pull up circuit 416, thereby preventing reverse current flow between the input circuit 304 and the output circuit 306.

It will be appreciated that in a further embodiment, the input circuit 304 may comprise the pull down circuit 420 and the output circuit 306 may comprise the pull up circuit 416.

In the present embodiment both the first and second voltage domains may be regular domains (in that they are both non-flying voltage domains).

It will be appreciated that in embodiments of the present disclosure a constant current flow might happen, and the inclusion of cascodes, for example as shown in FIGS. 5 and 6, prevent a permanent current flow. The following example relates to a specific embodiment of the level shifter 300 of FIG. 6:
1. P-MOS 42 turns on
2. Zener-diode 61 and cascode n-MOS conduct
3. Node 62 is pulled up thus n-MOS 47 turns on
4. Node 64 goes low (to voltage Vssls) and n-MOS 44 turns off.
5. Node 62 goes up until the cascode 43 turns off and no current except leakage flows. Due to this leakage node 62 might be slightly below Vddls, approximately at the threshold of the cascode 43

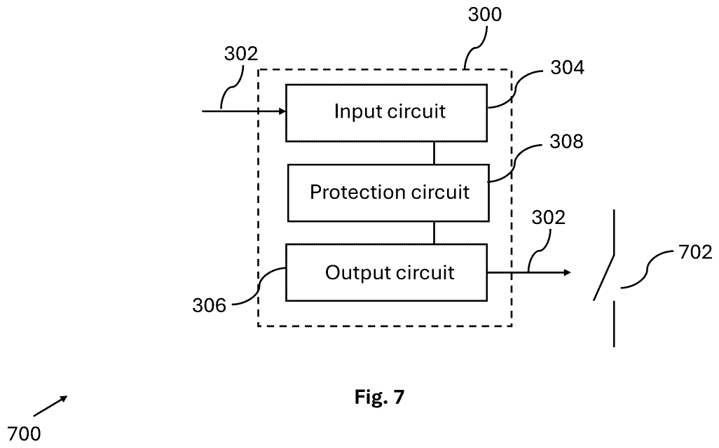

FIG. 7 is a schematic of a power converter system 700 comprising the level shifter 300 and a power switch 702 in accordance with a fifth embodiment of the present disclosure.

It will be appreciated that the level shifter 300 may be implemented using any of the specific embodiments described herein, in accordance with the understanding of the skilled person. It will be appreciated that the schematic shown in FIG. 7 may be considered as a power converter sub-system, with the full power converter system comprising additional components for power conversion.

In the present example, the power switch 702 is configured to operate in the second voltage domain. The level shifter 300 is configured to convert the voltage signal 302 from the first voltage domain to the second voltage domain prior to the voltage signal 302 being provided to the power switch 702. The voltage signal 302 may, for example, be a control signal used to drive the switching operation of the power switch 702, with the level shifter 300 being used to shift the voltage signal 302 from one voltage domain to the voltage domain of the power switch 702 to enable to power switch 702 to be controlled using the voltage signal 302.

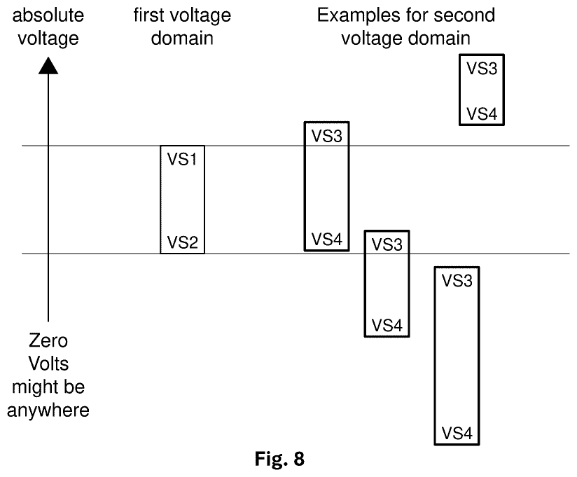

FIG. 8 is a graph showing the relationship between the first voltage domain and examples of the second voltage domain.

The supply voltages of the input domain VS1-VS2 and the output domain (VS3-VS4) may always be positive, and may be constant but unequal.

It will be appreciated that VS1 is labelled as vbat in some of the specific embodiments of the present disclosure and VS2 is labelled as vss or GND in some of the specific embodiments of the present disclosure such that VS1-VS2 may be written as vbat-vss or vbat-GND.

It will be appreciated that VS3 is labelled as vddFly in some of the specific embodiments of the present disclosure and VS4 is labelled as vssFly in some of the specific embodiments of the present disclosure such that VS3-VS4 may be written as vddFly-vssFly.

It will be appreciated that in specific embodiments vddFly may be a local supply voltage (local vdd) and vssFly may be a local ground (local GND).

It will also be appreciated that dependent on convention, VS1-VS2 may be written as VS2-VS1; and VS3-VS4 may be written as VS4-VS3.

In real applications the voltages domains may vary (for example during system start-up) and they are often spiky. This is especially the case if they are buffered with small capacitors which may have real parasitics (such as the equaivalent series resistance (ESR), and the equivalent series inductance (ESL)). It will be appreciated that the relation between VS1 and VS3 or VS4 may not be fixed. For example, VS1 can be greater than VS2, VS3 and VS4; between VS2, VS3 and VS4; or less than VS2, VS3 and VS4. The same applies to the relation between VS2 with VS3 and VS4. Some possible combinations are presented in FIG. 8.

Level shifter embodiments of the present disclosure may function with input and output domains which may have any relation to each other. These input/output relationships may change very rapidly over time. For example, in multi-level DC/DC converters (MLC) converters the ground of one voltage domain may jump above or below the other domain within nanoseconds or even in some hundreds of picoseconds if (pairs of) power-switches are opened and closed. Here “above” and “below” do not only mean several volts above and only one diode voltage below but several volts, tens or hundreds of volts above and below a ground voltage vss. It will be appreciated that this is an example with diode conduction at vss. In a case of diode conduction at vdd, it is the opposite.

Level shifter embodiments of the present disclosure may function as high-voltage level-shifters for flying voltage domains. In some topologies like the power stages of Multilevel DC/DC converters (MLCs) the aforementioned flying output voltage domains might have their ground changing from above to below the GND of the quiet input domain and vice versa. Embodiments of the present disclosure facilitate this operation in one single level-shifter.

Embodiments of the present disclosure can also be applied to static level-shifters where the high voltage (HV) transistors generating the current pulses are permanently on and the cascode transistors stop the current pulse when the cross coupled inverters flip.

Embodiments of the present disclosure may avoid electric loads at auxiliary voltages. In current practice level-shifters the signal is often shifted to the (e.g. negative output voltage Vout) output domain and then level-shifted again to the flying domain (e.g. of a flying capacitor), for example as described previously in relation to FIG. 1A. Furthermore, embodiments of the present disclosure may save wiring connections to auxiliary voltages.

Various improvements and modifications may be made to the above without departing from the scope of the disclosure.

1. A level shifter for shifting a voltage signal from a first voltage domain to a second voltage domain comprising:
an input circuit configured to receive the voltage signal in the first voltage domain;
an output circuit configured to output the voltage signal in the second voltage domain; and
a protection circuit configured to prevent reverse current flow between the input circuit and the output circuit.

2. The level shifter of claim 1, wherein the first voltage domain is a flying voltage domain and/or the second voltage domain is a flying voltage domain.

3. The level shifter of claim 1, wherein the input circuit is configured to operate in the first voltage domain and the output circuit is configured to operate in the second voltage domain.

4. The level shifter of claim 1, wherein:
the first voltage domain is the voltage range from a first supply voltage to a second supply voltage; and
the second voltage domain is the voltage range from a third supply voltage to a fourth supply voltage.

5. The level shifter of claim 1, wherein the protection circuit comprises one or more rectifier elements, each of the rectifier elements being configured to prevent reverse current flow between the input circuit and the output circuit.

6. The level shifter of claim 5, wherein one or more of the rectifier elements comprises a diode or a bipolar transistor.

7. The level shifter of claim 6, wherein the diode is a p/n diode, a Zener diode or a Schottky diode.

8. The level shifter of claim 1, wherein:
the input circuit comprises:
a pull up circuit coupled to the output circuit via a first portion of the protection circuit, the first portion of the protection circuit being configured to prevent reverse current flow from the output circuit to the pull up circuit, thereby preventing reverse current flow between the input circuit and the output circuit; and/or
a pull down circuit coupled to the output circuit via a second portion of the protection circuit, the second portion of the protection circuit being configured to prevent reverse current flow from the pull down circuit to the output circuit, thereby preventing reverse current flow between the input circuit and the output circuit.

9. The level shifter of claim 8, wherein:
the output circuit comprises a latch circuit configured to provide the voltage signal in the second voltage domain; wherein:
the pull up circuit is coupled to the latch circuit via the first portion of the protection circuit, the first portion of the protection circuit being configured to prevent reverse current flow from the latch circuit to the pull up circuit, thereby preventing reverse current flow between the input circuit and the output circuit; and/or
the pull down circuit is coupled to the latch circuit via the second portion of the protection circuit, the second portion of the protection circuit being configured to prevent reverse current flow from the pull down circuit to the latch circuit, thereby preventing reverse current flow between the input circuit and the output circuit.

10. The level shifter of claim 9, wherein:
the first voltage domain is the voltage range from a first supply voltage to a second supply voltage;
the second voltage domain is the voltage range from a third supply voltage to a fourth supply voltage;
the second voltage domain is positive when:
i) the fourth supply voltage is greater than the third supply voltage; and/or
ii) the second supply voltage is greater than the first supply voltage; and/or
iii) the third supply voltage is greater than the first supply voltage;
the second voltage domain is negative when:
i) the second supply voltage is greater than the fourth supply voltage; and/or
ii) the first supply voltage is greater than the third supply voltage; and
the pull up circuit is configured to control a state of the latch circuit based on the voltage signal in the first domain, as received, when the second voltage domain is negative; and
the pull down circuit is configured to control the state of the latch circuit based on the voltage signal in the first domain, as received, when the second voltage domain is positive.

11. The level shifter of claim 10, wherein:
the pull up circuit is configured to control the state of the latch circuit by providing a first pull up signal to a first input terminal of the latch circuit and/or by providing a second pull up signal to a second input terminal of the latch circuit; and
the pull down circuit is configured to control the state of the latch circuit by providing a first pull down signal to the first input terminal of the latch circuit and/or by providing a second pull down signal to the second input terminal of the latch circuit.

12. The level shifter of claim 11, wherein:
the first pull up signal is a first pull up current pulse;
the second pull up signal is a second pull up current pulse;
the first pull down signal is a first pull down current pulse; and
the second pull down signal is a second pull down current pulse.

13. The level shifter of claim 12, wherein:
the first pull up current pulse is a set pulse for the latch circuit and the second pull up current pulse is a reset pulse for the latch circuit; or
the first pull up current pulse is a reset pulse for the latch circuit and the second pull up current pulse is a set pulse for the latch circuit; or
the first pull down current pulse is a set pulse for the latch circuit and the second pull down current pulse is a reset pulse for the latch circuit; or
the first pull down current pulse is a reset pulse for the latch circuit and the second pull down current pulse is a set pulse for the latch circuit.

14. The level shifter of claim 9, wherein the latch circuit comprises a cross coupled inverter pair.

15. The level shifter of claim 14, wherein:
the output circuit comprises a common mode rejection circuit coupled to the latch circuit; and
the latch circuit is configured to provide the voltage signal in the second voltage domain via the common mode rejection circuit.

16. The level shifter of claim 9, comprising:
a first cascode circuit coupled between the first portion of the protection circuit and the latch circuit; and
a second cascode circuit coupled between the second portion of the protection circuit and the latch circuit.

17. The level shifter of claim 11, wherein:
the protection circuit comprises a first rectifier element, a second rectifier element, a third rectifier element and a fourth rectifier element;
each of the first, second, third and fourth rectifier elements are configured to prevent reverse current flow between the input circuit and the output circuit;
the first rectifier element is coupled to the first input terminal of the latch circuit and the third rectifier element;
the second rectifier element is coupled to the second input terminal of the latch circuit and the fourth rectifier element;
the pull up circuit is configured to provide the first pull up signal to the first input terminal via the first rectifier element;
the pull up circuit is configured to provide the second pull up signal to the second input terminal via the second rectifier element;
the pull down circuit is configured to provide the first pull down signal to the first input terminal via the third rectifier element; and
the pull down circuit is configured to provide the second pull down signal to the second input terminal via the fourth rectifier element.

18. The level shifter of claim 17, wherein:
the pull up circuit comprises a first pull up switch coupled to the first rectifier element and a second pull up switch coupled to the second rectifier element; and
the pull down circuit comprises a first pull down switch coupled to the third rectifier element and a second pull down switch coupled to the fourth rectifier element.

19. The level shifter of claim 18, wherein:
the pull up circuit comprises:
a first inverting AND gate configured to:
i) receive the voltage signal in the first domain and a first indicator signal, the first indicator signal being in a high state when the second domain is negative and in a low state when the second domain is positive;
ii) output a first inverting AND gate output signal;
iii) provide the first inverting AND gate output signal to control the switching operation of the second pull up switch; and
a first inverter configured to:
i) receive the first inverting AND gate output signal;
ii) provide the inverted first inverting AND gate output signal to control the switching operation of the first pull up switch; and
the pull down circuit comprises:
a second inverting AND gate configured to:
i) receive the voltage signal in the first domain and a second indicator signal, the second indicator signal being in a high state when the second domain is positive and in a low state when the second domain is negative;
ii) output a second inverting AND gate output signal; and
iii) provide the second inverting AND gate output signal to control the switching operation of the second pull down switch; and
a second inverter configured to:
i) receive the second inverting AND gate output signal;
ii) provide the inverted second inverting AND gate output signal to control the switching operation of the first pull down switch.

20. The level shifter of claim 1, wherein:
the input circuit comprises a pull up circuit and the output circuit comprises a pull down circuit; or
the input circuit comprises the pull down circuit and the output circuit comprises the pull up circuit; and
the pull up circuit is coupled to the pull down circuit via the protection circuit, the protection circuit being configured to prevent reverse current flow from the pull down circuit to the pull up circuit, thereby preventing reverse current flow between the input circuit and the output circuit.

21. A power converter system comprising:
a level shifter for shifting a voltage signal from a first voltage domain to a second voltage domain comprising:
i) an input circuit configured to receive the voltage signal in the first voltage domain;
ii) an output circuit configured to output the voltage signal in the second voltage domain; and
iii) a protection circuit configured to prevent reverse current flow between the input circuit and the output circuit; and
a power switch configured to operate in the second voltage domain; wherein:
the level shifter is configured to convert the voltage signal from the first voltage domain to the second voltage domain prior to the voltage signal being provided to the power switch.

22. A method of shifting a voltage signal from a first voltage domain to a second voltage domain using a level shifter, the method comprising:
receiving the voltage signal in the first voltage domain using an input circuit;
outputting the voltage signal in the second voltage domain using an output circuit; and
preventing reverse current flow between the input circuit and the output circuit using a protection circuit.
